(19) United States
(12) Patent Application Publication
(10) Pub. No.: US 2019/0058454 A1
(43) Pub. Date: Feb. 21, 2019

(54) ELASTIC WAVE APPARATUS

(71) Applicant: Murata Manufacturing Co., Ltd., Nagaokakyo-shi (JP)

(72) Inventor: Shinichi NAKAMURA, Nagaokakyo-shi (JP)

(21) Appl. No.: 16/167,608

(22) Filed: Oct. 23, 2018

Related U.S. Application Data
(63) Continuation of application No. PCT/JP2017/004749, filed on Feb. 9, 2017.

(30) Foreign Application Priority Data
May 17, 2016 (JP) 2016-098461

(51) Int. Cl. H03H 9/145; H03H 9/25; H03H 9/02

(52) U.S. Cl. CPC H03H 9/1457; H03H 9/25; H03H 9/02023; H03H 9/02992; H03H 9/14541

(57) ABSTRACT

An elastic wave apparatus includes a piezoelectric substrate and an IDT electrode. The IDT electrode includes a pair of busbars that face each other, electrode fingers, and dummy electrode fingers. At least the electrode fingers or the dummy electrode fingers each include a distal end having a width less than a width of another portion of the electrode finger or the dummy electrode finger including the distal end. A first straight line extending along a center or approximate center of one of the electrode fingers and a second straight line extending along a center or approximate center of one of the dummy electrode fingers facing the one of the electrode fingers are at different positions in an elastic wave propagation direction.

### CROSS REFERENCE TO RELATED APPLICATIONS

This application claims the benefit of priority to Japanese Patent Application No. 2016-098461 filed on May 17, 2016 and is a Continuation Application of PCT Application No. PCT/JP2017/004749 filed on Feb. 9, 2017. The entire contents of each application are hereby incorporated herein by reference.

### BACKGROUND OF THE INVENTION

### 1. Field of the Invention

The present invention relates to an elastic wave apparatus for use as, for example, a resonator or a band-pass filter.

### 2. Description of the Related Art

Elastic wave apparatuses have been widely used as resonators and band-pass filters.

Japanese Unexamined Patent Application Publication No. 2009-38718 discloses an elastic wave filter including a piezoelectric substrate and an IDT electrode provided on the piezoelectric substrate. The IDT electrode includes a first busbar, a plurality of first electrode fingers connected to the first busbar, a second busbar that faces the first busbar, and a plurality of second electrode fingers connected to the second busbar. The IDT electrode further includes first dummy electrode fingers that are connected to the first busbar and face the second electrode fingers and second dummy electrode fingers that are connected to the second busbar and face the first electrode fingers. Thus, the IDT electrode included in the elastic wave filter according to Japanese Unexamined Patent Application Publication No. 2009-38718 includes dummy electrode fingers including the first and second dummy electrode fingers, so that unwanted waves in the pass band are suppressed and insertion loss is reduced.

When the IDT electrode includes the dummy electrode fingers as in the elastic wave filter described in Japanese Unexamined Patent Application Publication No. 2009-38718, the insertion loss is able to be reduced. However, there is a risk that the IDT electrode will be degraded due to electrostatic discharge caused by the potential difference between the dummy electrode fingers and the electrode fingers that face the dummy electrode fingers. Thus, the elastic wave filter according to Japanese Unexamined Patent Application Publication No. 2009-38718 does not have sufficient electrostatic discharge (ESD) resistance.

### SUMMARY OF THE INVENTION

Preferred embodiments of the present invention provide elastic wave apparatuses having high ESD resistance and low insertion loss.

An elastic wave apparatus according to a preferred embodiment of the present invention includes a piezoelectric substrate and an IDT electrode provided on the piezoelectric substrate. The IDT electrode includes a pair of busbars that face each other, a plurality of electrode fingers, each including one end connected to one of the busbars, and a plurality of dummy electrode fingers, each including one end connected to one of the busbars that differs from the busbar to which the electrode fingers are connected and facing a distal end of a corresponding one of the electrode fingers with a gap therebetween in a direction in which the electrode fingers extend. At least one finger of at least the first electrode fingers or the second dummy electrode fingers includes a distal end having a width less than a width of another portion of the electrode finger or the dummy electrode finger including the distal end. A first straight line and a second straight line are at different positions in an elastic wave propagation direction, the first straight line passing through a center or approximate center of the distal end of one of the electrode fingers in a width direction and extending parallel or substantially parallel to the direction in which the electrode fingers extend, the second straight line passing through a center or approximate center of the distal end of one of the dummy electrode fingers in the width direction and extending parallel or substantially parallel to a direction in which the dummy electrode fingers extend, the one of the dummy electrode fingers facing the one of the electrode fingers through which the first straight line extends.

In an elastic wave apparatus according to a preferred embodiment of the present invention, the at least one finger of at least the first electrode fingers or the second dummy electrode fingers includes a portion having a width that decreases toward the distal end of the electrode finger or the dummy electrode finger.

In an elastic wave apparatus according to a preferred embodiment of the present invention, both of the first electrode finger and the second dummy electrode finger each include the distal end having the width less than the width of the other portion of the electrode finger or the dummy electrode finger including the distal end. In this case, the ESD resistance is further increased and the insertion loss is further reduced.

In an elastic wave apparatus according to a preferred embodiment of the present invention, a distance between the first and second straight lines is less than about ½ of a width of the electrode finger. In this case, the insertion loss is more reliably reduced.

In an elastic wave apparatus according to a preferred embodiment of the present invention, the gap between the distal end of the electrode finger and the distal end of the corresponding one of the dummy electrode fingers is smallest among gaps between electrode fingers connected to different potentials. In this case, the ESD resistance is further increased.

In an elastic wave apparatus according to a preferred embodiment of the present invention, the IDT electrode includes first and second busbars that face each other; a plurality of first electrode fingers, each including one end connected to the first busbar; a plurality of second electrode fingers, each including one end connected to the second busbar, the second electrode fingers being interdigitated with the first electrode fingers; a plurality of first dummy electrode fingers, each including one end connected to the first busbar and facing a distal end of a corresponding one of the second electrode fingers with a gap therebetween; and a plurality of second dummy electrode fingers, each including one end connected to the second busbar and facing a distal end of a corresponding one of the first electrode fingers with a gap therebetween.

Preferred embodiments of the present invention provide elastic wave apparatuses having high ESD resistance and low insertion loss.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan view of an elastic wave apparatus according to a first preferred embodiment of the present invention.

FIG. 2 is an enlarged schematic plan view of a portion of the elastic wave apparatus according to the first preferred embodiment of the present invention in which a first electrode finger and a second dummy electrode finger face each other.

FIG. 3 is a schematic diagram illustrating a comparison between a distance g2 between a distal end of a first electrode finger and a distal end of a second dummy electrode finger in the elastic wave apparatus according to the first preferred embodiment of the present invention and a distance g1 between a distal end of a first electrode finger and a distal end of a second dummy electrode finger in an elastic wave apparatus according to a comparative example.

FIG. 4 is an enlarged schematic plan view of a portion of an elastic wave apparatus according to a second preferred embodiment of the present invention in which a first electrode finger and a second dummy electrode finger face each other.

FIG. 5 is a graph showing the ESD resistances of elastic wave apparatuses according to an example of a preferred embodiment of the present invention and a comparative example.

FIG. 6 is an enlarged schematic plan view of a portion of an elastic wave apparatus according to a comparative example in which a first electrode finger and a second dummy electrode finger face each other.

### DETAILED DESCRIPTION OF THE PREFERRED EMBODIMENTS

Preferred embodiments of the present invention will be described with reference to the accompanying drawings.

It is to be noted that each of the preferred embodiments described in this specification is illustrative, and partial replacements and combinations of the structures of different preferred embodiments are possible.

### First Preferred Embodiment

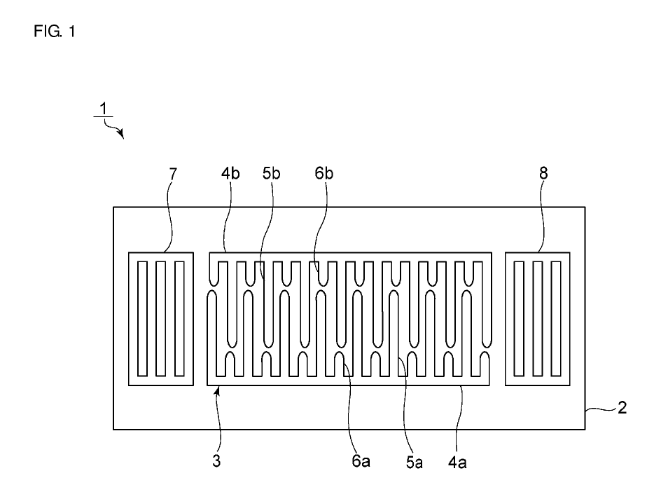

FIG. 1 is a schematic plan view of an elastic wave apparatus according to a first preferred embodiment of the present invention. Referring to FIG. 1, an elastic wave apparatus 1 includes a rectangular or substantially rectangular plate-shaped piezoelectric substrate 2. The piezoelectric substrate 2 is made of an appropriate piezoelectric material. Examples of the piezoelectric material include piezoelectric single crystals and piezoelectric ceramics. Examples of piezoelectric single crystals include LiNbO₃, K₂NbO₃, LiTaO₃, quartz crystal, and langasite. Examples of piezoelectric ceramics include PZT.

An IDT electrode 3 is provided on the piezoelectric substrate 2. Reflectors 7 and 8 are disposed on both sides of the IDT electrode 3 in an elastic wave propagation direction to define a one-port elastic wave resonator. Thus, the elastic wave apparatus 1 is preferably a one-port elastic wave resonator, for example. An elastic wave apparatus according to a preferred embodiment of the present invention may instead be another type of elastic wave apparatus, such as an elastic wave filter, for example.

The IDT electrode 3 is preferably made of a metal material, such as Al, Cu, Pt, Au, Ag, Ti, Ni, Cr, Mo, or W, or an alloy of these metals. The IDT electrode 3 may be a single-layer metal film or a multilayer metal film in which two or more types of metal films are laminated together.

As illustrated in FIG. 1, the IDT electrode 3 includes first and second busbars 4a and 4b, a plurality of first electrode fingers 5a, a plurality of second electrode fingers 5b, a plurality of first dummy electrode fingers 6a, and a plurality of second dummy electrode fingers 6b. The first and second busbars 4a and 4b face each other.

One end of each of the first electrode fingers 5a is connected to the first busbar 4a. One end of each of the second electrode fingers 5b is connected to the second busbar 4b. The first and second electrode fingers 5a and 5b are interdigitated.

One end of each of the first dummy electrode fingers 6a is connected to the first busbar 4a. Each first dummy electrode finger 6a faces the distal end of a corresponding one of the second electrode fingers 5b with a gap therebetween in the direction in which the second electrode fingers 5b extend. One end of each of the second dummy electrode fingers 6b is connected to the second busbar 4b. Each second dummy electrode finger 6b faces the distal end of a corresponding one of the first electrode fingers 5a with a gap therebetween in the direction in which the first electrode fingers 5a extend. Since the first and second dummy electrode fingers 6a and 6b are provided, unwanted waves are reduced or prevented and insertion loss is reduced. The direction in which the first and second electrode fingers 5a and 5b extend is orthogonal or substantially orthogonal to the elastic wave propagation direction. The direction in which the first and second electrode fingers 5a and 5b extend is orthogonal or substantially orthogonal to the direction in which the first and second busbars 4a and 4b extend. The direction in which the first and second electrode fingers 5a and 5b extend is parallel or substantially parallel to the direction in which the first and second dummy electrode fingers 6a and 6b extend.

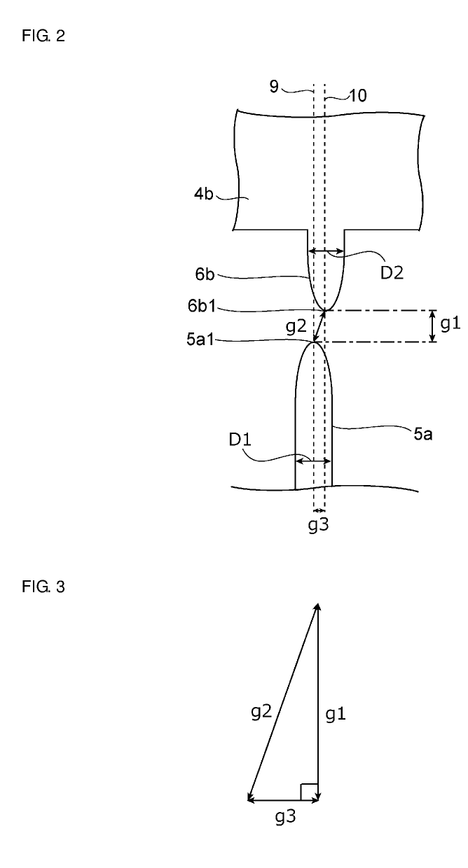

FIG. 2 is an enlarged schematic plan view of a portion of the elastic wave apparatus according to the first preferred embodiment of the present invention in which one of the first electrode fingers 5a and one of the second dummy electrode fingers 6b face each other.

Referring to FIG. 2, in the first preferred embodiment, a distal end 5a 1 of each first electrode finger 5a has a width less than a width D1 of another portion of the first electrode finger 5a. More specifically, a portion of the first electrode finger 5a including the distal end 5a 1 preferably has, for example, a semielliptical shape in plan view. Accordingly, the first electrode finger 5a includes a portion whose width decreases toward the distal end 5a 1. The first electrode finger 5a also includes a portion having a constant width that extends toward the first busbar 4a. The constant width of this portion is the width D1.

Similarly, a distal end 6b 1 of each second dummy electrode finger 6b has a width less than a width D2 of another portion of the second dummy electrode finger 6b. More specifically, a portion of the second dummy electrode finger 6b including the distal end 6b 1 preferably has, for example, a semielliptical shape in plan view. Accordingly, the second dummy electrode finger 6b includes a portion whose width decreases toward the distal end 6b 1. The second dummy electrode finger 6b also includes a portion having a constant width that extends toward the second busbar 4b. The constant width of this portion is the width D2.

Referring to FIG. 2, a first straight line 9 passes through the center or approximate center of the distal end 5a 1 of the first electrode finger 5a in the width direction and extends parallel or substantially parallel to the direction in which the first electrode finger 5a extends. A second straight line 10 passes through the center or approximate center of the distal end 6b 1 of the second dummy electrode finger 6b, which faces the first electrode finger 5a, in the width direction and extends parallel or substantially parallel to the direction in which the second dummy electrode finger 6b extends. In the present preferred embodiment, the first and second straight lines 9 and 10 are at different positions in the elastic wave propagation direction.

Thus, in the present preferred embodiment, the first electrode fingers 5a and the second dummy electrode fingers 6b that face each other each include a distal end having a width less than that of another portion thereof, and the first and second straight lines 9 and 10 are at different positions in the elastic wave propagation direction. Accordingly, the elastic wave apparatus 1 has high ESD resistance and low insertion loss.

This will be described in more detail by comparing the elastic wave apparatus according to the present preferred embodiment with an elastic wave apparatus according to a comparative example.

FIG. 6 is an enlarged schematic plan view of a portion of the elastic wave apparatus according to the comparative example in which a first electrode finger and a second dummy electrode finger face each other.

As illustrated in FIG. 6, in the elastic wave apparatus according to the comparative example, a first electrode finger 105a and a second dummy electrode finger 106b that face each other each include a distal end having a width equal to that of another portion thereof, and first and second straight lines 109 and 110 are at the same or approximately the same position in the elastic wave propagation direction. Accordingly, the distance between a distal end 105a 1 of the first electrode finger 105a and a distal end 106b 1 of the second dummy electrode finger 106b is gl in FIG. 6. The distance g1 in FIG. 6 is equal or substantially equal to the distance g1 between the first electrode finger 5a and the second dummy electrode finger 6b in the direction in which the first electrode finger 5a extends in FIG. 2.

In contrast, the elastic wave apparatus 1 according to the present preferred embodiment has the above-described characteristics and structure, and accordingly, the distance between the distal end 5a 1 of each first electrode finger 5a and the distal end 6b 1 of the corresponding second dummy electrode finger 6b is g2 in FIG. 2. In the elastic wave apparatus 1, the distance between the first and second straight lines 9 and 10 is g3 in FIG. 2. Thus, g1, g2, and g3 define a right triangle illustrated in FIG. 3. As illustrated in FIG. 3, g2 is the hypotenuse, and g1 and g3 are the other two sides of the right triangle. Therefore, g2 is greater than g1, and the distance between the distal end 5a 1 of each first electrode finger 5a and the distal end 6b 1 of the corresponding second dummy electrode finger 6b in the elastic wave apparatus 1 is greater than that in the elastic wave apparatus according to the comparative example. Accordingly, the elastic wave apparatus 1 has higher ESD resistance than that of the elastic wave apparatus according to the comparative example. This is confirmed by referring an Example of a preferred embodiment of the present invention and a Comparative Example described below.

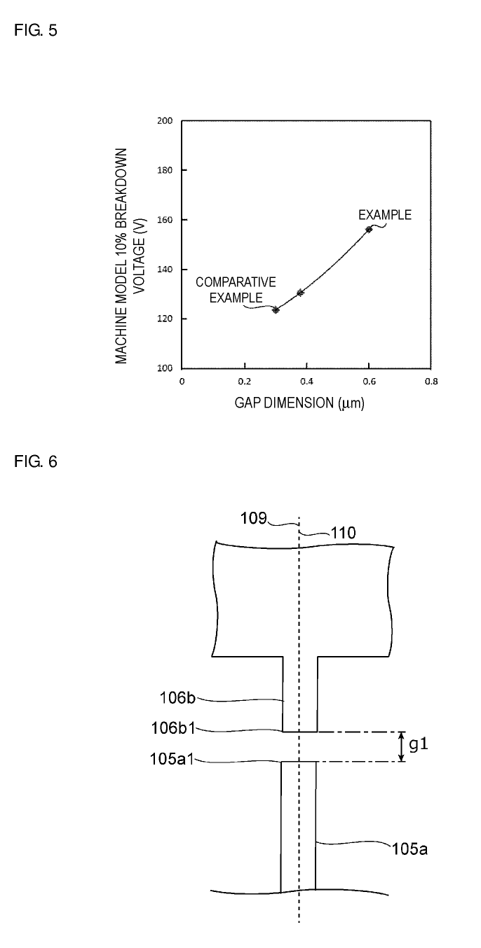

FIG. 5 is a graph showing the ESD resistances of elastic wave apparatuses according to the Example and the Comparative Example. The horizontal axis of the graph represents the gap dimension between the distal ends of each electrode finger and the corresponding dummy electrode finger. The vertical axis of the graph represents the machine model 10% breakdown voltage. One-port elastic wave resonators described below were used as the Example and the Comparative Example.

Piezoelectric Substrate: LiNbO₃ Substrate

IDT Electrode: Pt/Al

Number of Pairs of Electrode Fingers: 145 pairs

Electrode Finger Pitch: about 1.99 μm

Duty: about 0.5

The elastic wave apparatus 1 illustrated in FIGS. 1 and 2 (g1: about 0.3 μm, g2: about 0.6 μm, g3: about 0.52 μm) was used as the Example. The elastic wave apparatus illustrated in FIG. 6 (g1: about 0.3 μm) was used as Comparative Example.

As is clear from FIG. 5, the machine model 10% breakdown voltage of the Example was about 156.1 V, and the machine model 10% breakdown voltage of the Comparative Example was about 123.5 V. Thus, the ESD resistance of the Example is significantly greater than that of the Comparative Example.

When the length of each second dummy electrode finger 106b is reduced to increase g1 in the elastic wave apparatus of the Comparative Example, insertion loss cannot be sufficiently reduced. In contrast, g2 is able to be increased without reducing the length of each second dummy electrode finger 6b in the elastic wave apparatus 1. Accordingly, the elastic wave apparatus 1 has high ESD resistance and low insertion loss.

As illustrated in FIGS. 1 and 2, the elastic wave apparatus 1 is structured such that both of the first electrode fingers 5a and the second dummy electrode fingers 6b that face each other each include a distal end having a width less than that of another portion. According to a preferred embodiment of the present invention, at least one finger of at least the first electrode fingers or the second dummy electrode fingers includes a distal end having a width less than that of another portion. To further increase the ESD resistance and reduce the insertion loss, preferably, both of the first electrode finger and the second dummy electrode finger each include a distal end having a width less than that of another portion.

In the elastic wave apparatus 1, the gap (distance g2) between the distal end 5a 1 of each first electrode finger 5a and the distal end 6b 1 of the corresponding second dummy electrode finger 6b is smallest among gaps between electrode fingers connected to different potentials. Accordingly, the ESD resistance of the elastic wave apparatus 1 is further increased. According to a preferred embodiment of the present invention, preferably, the gap between the distal end of each first electrode finger and the distal end of the corresponding second dummy electrode finger is smallest among gaps between electrode fingers connected to different potentials.

The distance between the first straight line 9 and the second straight line 10 is preferably, for example, less than about ½ of the width of the first electrode finger 5a. When the distance between the first straight line 9 and the second straight line 10 is greater than or equal to about ½ of the width of the first electrode fingers 5a, the first electrode fingers 5a and the second dummy electrode fingers 6b do not face each other and the insertion loss may not be sufficiently reduced. Therefore, the insertion loss is more reliably reduced by setting the distance between the first straight line 9 and the second straight line 10 in the above-described range.

### Second Preferred Embodiment

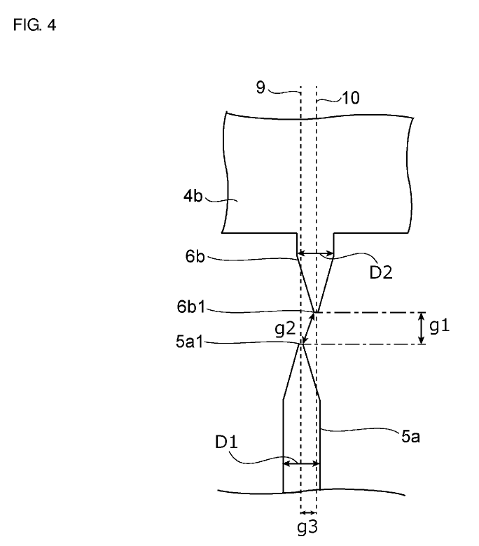

FIG. 4 is an enlarged schematic plan view of a portion of an elastic wave apparatus according to a second preferred embodiment of the present invention in which a first electrode finger and a second dummy electrode finger face each other.

Referring to FIG. 4, in the elastic wave apparatus according to the second preferred embodiment, a portion of each first electrode finger 5a including a distal end 5a 1 preferably has, for example, a trapezoidal shape in plan view. Accordingly, the first electrode finger 5a includes a portion whose width decreases toward the distal end 5a 1. Also, a portion of each second dummy electrode finger 6b including a distal end 6b 1 preferably has, for example, a trapezoidal shape in plan view. Accordingly, the second dummy electrode finger 6b includes a portion whose width decreases toward the distal end 6b 1. Other structures are the same or substantially the same as those in the first preferred embodiment.

Also in the elastic wave apparatus according to the second preferred embodiment, the first electrode fingers 5a and the second dummy electrode fingers 6b that face each other each include a distal end having a width less than that of another portion thereof, and the first straight line 9 and the second straight line 10 are at different positions in the elastic wave propagation direction. Accordingly, the elastic wave apparatus according to the second preferred embodiment has high ESD resistance and low insertion loss.

As described above, according to preferred embodiments of the present invention, the shapes of the distal ends of the first electrode fingers and the second dummy electrode fingers in plan view are not particularly limited as long as at least one finger of at least the first electrode fingers or the second dummy electrode fingers includes a distal end having a width less than that of another portion thereof.

Although the characteristics and structure of the first electrode fingers 5a and the second dummy electrode fingers 6b are described above in the first and second preferred embodiments, preferably, the second electrode fingers 5b and the first dummy electrode fingers 6a also have the same or substantially the same characteristics and structure. In other words, all of the electrode fingers and the dummy electrode fingers preferably have the characteristics and structure of the present invention. In such a case, the advantageous effects of preferred embodiments of the present invention are enhanced.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An elastic wave apparatus comprising:
a piezoelectric substrate; and
an IDT electrode provided on the piezoelectric substrate; wherein
the IDT electrode includes:
a pair of busbars that face each other;
a plurality of electrode fingers, each including one end connected to one of the busbars; and
a plurality of dummy electrode fingers, each including one end connected to one of the busbars that differs from the busbar to which the electrode fingers are connected and facing a distal end of a corresponding one of the electrode fingers with a gap therebetween in a direction in which the electrode fingers extend;
at least one finger of at least the electrode fingers or the dummy electrode fingers includes a distal end having a width less than a width of another portion of the at least one finger of at least the electrode fingers or the dummy electrode fingers including the distal end; and
a first straight line and a second straight line are at different positions in an elastic wave propagation direction, the first straight line passing through a center or approximate center of the distal end of one of the electrode fingers in a width direction and extending parallel or substantially parallel to the direction in which the electrode fingers extend, the second straight line passing through a center or approximate center of the distal end of one of the dummy electrode fingers in the width direction and extending parallel or substantially parallel to a direction in which the dummy electrode fingers extend, the one of the dummy electrode fingers facing the one of the electrode fingers through which the first straight line extends.

2. The elastic wave apparatus according to claim 1, wherein the at least the electrode fingers or the dummy electrode fingers includes a portion having a width that decreases toward the distal end of the at least the electrode fingers or the dummy electrode fingers.

3. The elastic wave apparatus according to claim 1, wherein both of the at least one finger of the electrode fingers and the at least one finger of the dummy electrode fingers each include the distal end having the width less than the width of the other portion of the electrode finger or the dummy electrode finger including the distal end.

4. The elastic wave apparatus according to claim 1, wherein a distance between the first and second straight lines is less than about ½ of a width of the electrode fingers.

5. The elastic wave apparatus according to claim 1, wherein the gap between the distal end of the electrode finger and the distal end of the corresponding one of the dummy electrode fingers is smallest among gaps between electrode fingers connected to different potentials.

6. An elastic wave apparatus comprising:
a piezoelectric substrate; and
an IDT electrode provided on the piezoelectric substrate; wherein
the IDT electrode includes:
first and second busbars that face each other;
a plurality of first electrode fingers, each including one end connected to the first busbar;
a plurality of second electrode fingers, each including one end connected to the second busbar, the second electrode fingers being interdigitated with the first electrode fingers;
a plurality of first dummy electrode fingers, each including one end connected to the first busbar and facing a distal end of a corresponding one of the second electrode fingers with a gap therebetween; and
a plurality of second dummy electrode fingers, each including one end connected to the second busbar and facing a distal end of a corresponding one of the first electrode fingers with a gap therebetween;
at least one finger of at least one of the first and second electrode fingers or at least one of the second and first dummy electrode fingers includes a distal end having a width less than a width of another portion of the at least one of the first and second electrode fingers or at least one of the second and first dummy electrode fingers including the distal end; and
a first straight line and a second straight line are at different positions in an elastic wave propagation direction, the first straight line passing through a center or approximate center of the distal end of one of the first and second electrode fingers in a width direction and extending parallel or substantially parallel to the direction in which the first and second electrode fingers extend, the second straight line passing through a center or approximate center of the distal end of one of the second and first dummy electrode fingers in the width direction and extending parallel or substantially parallel to a direction in which the first and second dummy electrode fingers extend, the one of the second and first dummy electrode fingers facing the one of the first and second electrode fingers through which the first straight line extends.

7. The elastic wave apparatus according to claim 6, wherein the at least one finger of at least the first and second electrode fingers or the second and first dummy electrode fingers includes a portion having a width that decreases toward the distal end of the at least one finger of at least the first and second electrode fingers or the second and first dummy electrode fingers.

8. The elastic wave apparatus according to claim 6, wherein both of the at least one finger of at least the first and second electrode fingers and the second and first dummy electrode fingers each include the distal end having the width less than the width of the other portion of the at least one finger of at least the first and second electrode fingers or the second and first dummy electrode fingers including the distal end.

9. The elastic wave apparatus according to claim 6, wherein a distance between the first and second straight lines is less than about ½ of a width of the first and second electrode fingers.

10. The elastic wave apparatus according to claim 6, wherein the gap between the distal end of the electrode finger and the distal end of the corresponding one of the dummy electrode fingers is smallest among gaps between electrode fingers connected to different potentials.
